(19) United States
(12) Patent Application Publication
(10) Pub. No.: US 2026/0367118 A1
(43) Pub. Date: Nov. 19, 2026

(54) CURRENT MEASUREMENT IN A GALLIUM NITRIDE (GaN)-BASED HALF-BRIDGE IC FOR POWER APPLICATIONS

(71) Applicant: Robert Bosch GmbH, Stuttgart (DE)

(72) Inventors: Joachim Joos, Gerlingen (DE); Manuela Fischer, Reutlingen (DE)

(21) Appl. No.: 19/649,565

(22) Filed: Apr. 16, 2026

(30) Foreign Application Priority Data
May 2, 2025 (DE) 10 2025 116 857.1

(51) Int. Cl. G01R 19/00; G01R 17/10; H03H 7/38; H03K 17/14

(52) U.S. Cl. CPC G01R 19/0092; G01R 17/10; H03H 7/38; H03K 17/145; H03K 2217/0027; H03K 2217/0072

(57) ABSTRACT

Improved current measurement in a gallium nitride (GaN)-based half-bridge IC for power applications.

### BACKGROUND INFORMATION

GaN components are characterized by high switching speeds and low switching losses. For reliable and safe control of these components, precise and fast current measurement is essential. However, conventional current sensors such as Hall sensors, shunts or SMD resistors are large compared to GaN ICs and introduce additional parasitic elements into the current path. Furthermore, due to power dissipation, they can cause an undesired local temperature increase. Their integration, in particular in monolithic half-bridges, is difficult.

FIG. 1 shows a simplified circuit for current measurement using a power FET and a sense FET in a common-drain configuration. The power FET is the main transistor that switches the load current. Its drain is connected to the node VDRAIN_POWER, which represents the output of the circuit and leads to the load.

The sense FET serves to measure the current through the power FET. It is connected in a common-drain configuration, i.e., its drain is connected to the drain of the power FET.

Both the power FET and the sense FET share the gate connection VGATE and the source connection VSS. This is a key feature of the circuit. Since both transistors receive the same gate signal, they switch simultaneously. The common source connection is important for the current measurement, since the current through the sense FET is proportional to the current through the power FET.

Most current GaN integration technologies provide transistors having fixed channel lengths. The only free design parameter is the gate width. The gate width can be variably selected by changing the total number of gate fingers connected in parallel in order to define the Rdson desired by the developer for an application. Although not explicitly shown in the figure, it is important to understand that the power FET and the sense FET have different channel widths. The power FET has a significantly larger channel width than the sense FET. This results in a defined current ratio (KSENSE) between the two transistors. The KSENSE is defined by the ratio of the gate widths of the power transistor and the sense transistor. The current through the sense FET is substantially smaller than the current through the power FET, which provides for a low-loss current measurement.

At the drain connection of the power FET, to which the load is connected, the actual power is switched. The voltage at this node is denoted as VDRAIN_POWER.

Since the sense FET is connected in a common-drain configuration, the drain connection of the sense FET is directly connected to the drain of the power FET. The voltage at this node is denoted as VDRAIN_SENSE and serves as a measurement point for the current measurement.

At the gate connection VGATE of both transistors, the control signal is applied that controls the switching states of the transistors.

The source connection VSS of both transistors is connected to ground.

In summary, FIG. 1 shows the basic configuration of the integrated sense FET for current measurement. Due to the common gate and source connection and the different gate widths, a defined current ratio between the power FET and the sense FET is established, which can be utilized for current measurement.

FIG. 2 shows a circuit similar to FIG. 1, however in a common-source configuration. This means that the source connections of the transistors are now separated and each have their own measurement point.

As in FIG. 1, the power FET is the main transistor for switching the load current. Its drain is connected to the node VDRAIN. The sense FET serves for current measurement. In contrast to FIG. 1, it is connected here in a common-source configuration, as a result of which the source connections are separated.

The power FET has its own source connection VSOURCE_POWER and the sense FET has its own source connection VSOURCE_SENSE. This provides for the separate measurement of the source voltages and thus the current through each transistor. Both transistors share the gate connection VGATE. In contrast to FIG. 1, the drain connections of the transistors are also connected here and are designated by the node VDRAIN.

As in FIG. 1, the power FET and the sense FET have different gate widths in order to achieve a defined current ratio (KSENSE).

The common drain connection of both transistors is VDRAIN. The load current flows here.

The common gate connection of both transistors is VGATE. The applied control signal controls the switching states of both transistors.

VSOURCE_POWER is the source connection of the power FET. The voltage at this node is denoted as VSOURCE_POWER.

VSOURCE_SENSE is the source connection of the sense FET. The voltage at this node is denoted as VSOURCE_SENSE and serves as a measurement point for the current measurement.

The decisive difference relative to FIG. 1 is the common-source configuration of the sense FET. Due to the separated source connections, the voltages VSOURCE_POWER and VSOURCE_SENSE can be separately measured, which provides for an alternative method for current measurement. However, this configuration is more susceptible to inaccuracies due to parasitic inductances of the bond wires, which are compensated for in the present disclosure by a matched impedance network.

Germany Patent No. DE 39 253 42 C2 describes an AB amplifier having a field effect transistor and a constant current source.

Europe Patent Application No. EP 2 254 215 A1 describes current measurement by means of a sense element on the printed circuit board.

Germany Patent application No. DE 10 2019 210 566 A1 relates to current measurement in an inductive load supplied by a half-bridge, using a synchronous measuring amplifier and a voltage follower.

Germany Patent Application No. DE 10 2020 131 640 A1 describes fast load current detection with a focus on peak current excursions.

### SUMMARY

The present disclosure integrates a programmable sense FET into the low-side power switch of the half-bridge. Both the power FET and the sense FET share the gate and source, but have different gate widths. The ratio of the gate widths is selected so that a defined current ratio KSENSE=I<sub>D, power</sub>/I<sub>D, sense</sub>between 500:1 and 3000:1 is achieved. This ratio provides for matching to different load currents and provides flexibility in the design.

The core of the present disclosure relates to the integration of the sense FET, matched source resistors and a matched impedance network.

The sense FET is integrated directly into the active region of the power FET in order to ensure optimum thermal coupling and minimization of parasitic effects. This integration reduces the required space and improves the measurement accuracy.

Integrated source resistors for the power FET and the sense FET are matched to one another according to the ratio R<sub>sense</sub>/R<sub>power</sub>=KSENSE. This precise matching is decisive for the accuracy of the current measurement.

An LC network, consisting of inductors and capacitors, is connected in series to the source resistors. This network compensates for the parasitic inductances of the bond wires that connect the source connections to the chip. The inductances are selected so that L<sub>sense</sub>/L<sub>power</sub>=KSENSE. The compensation minimizes the difference between the source voltages.

The example embodiment of the integrated sense FET in a common-drain configuration with a matched impedance network for the current measurement in GaN half-bridges provides a number of advantages over conventional solutions.

Due to the integration of the sense FET into the GaN half-bridge IC, the need for external current measurement components such as Hall sensors or shunts is eliminated. This results in a substantial reduction in the number of components and the required printed circuit board area, which is of great advantage in particular in space-critical applications. Miniaturization and higher power density are made possible.

The matched impedance network compensates for the parasitic inductances of the bond wires that connect the source connections of the transistors to the remainder of the circuit. These bond wires cause undesired voltage drops that can impair the accuracy of the current measurement. Compensating for these effects results in higher measurement accuracy and stability, in particular at high switching frequencies and currents.

The integrated solution provides for faster current measurement compared to external sensors. This is particularly important for GaN-based circuits operated at very high switching frequencies. The fast current measurement provides for the precise control and reliable protection of the circuit.

The integration of the sense FET and the associated reduction in the number of components result in lower material costs. In addition, the integration simplifies the manufacturing process and thus reduces production costs.

Due to the integration of the sense FET in immediate proximity to the power FET, a good thermal coupling between the two transistors is achieved. This results in improved temperature stability of the current measurement, since the temperature differences between the transistors are minimized.

The integration of the sense FET simplifies the design and layout of the circuit, since no external current measurement components and associated wiring must be taken into consideration. This reduces the development effort and the development time.

Fewer components mean fewer potential sources of error. Thus, the integration of the sense FET contributes to increasing the reliability of the overall system.

In summary, the present disclosure provides an elegant and efficient solution for current measurement in GaN half-bridges, characterized by high accuracy, speed, integration and cost advantages.

### BRIEF DESCRIPTION OF THE DRAWINGS

FIG. 1 shows a simplified circuit for current measurement using a power FET and a sense FET in a common-drain configuration.

FIG. 2 shows a circuit similar to FIG. 1, however in a common-source configuration.

FIG. 3 shows a low-side power switch having an integrated sense FET and the associated impedance matching.

FIG. 4 shows the complete test setup for characterization of the current measurement.

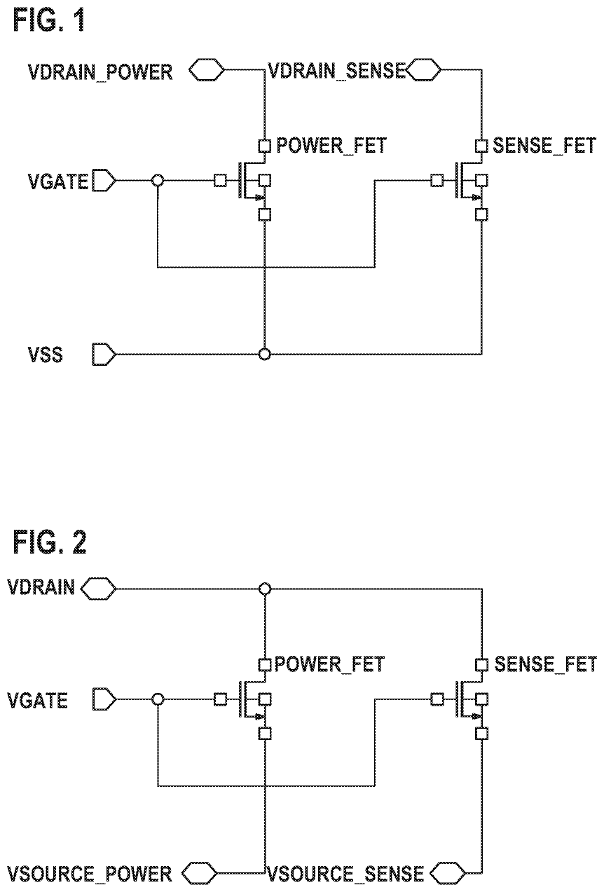

### DETAILED DESCRIPTION OF EXAMPLE EMBODIMENTS

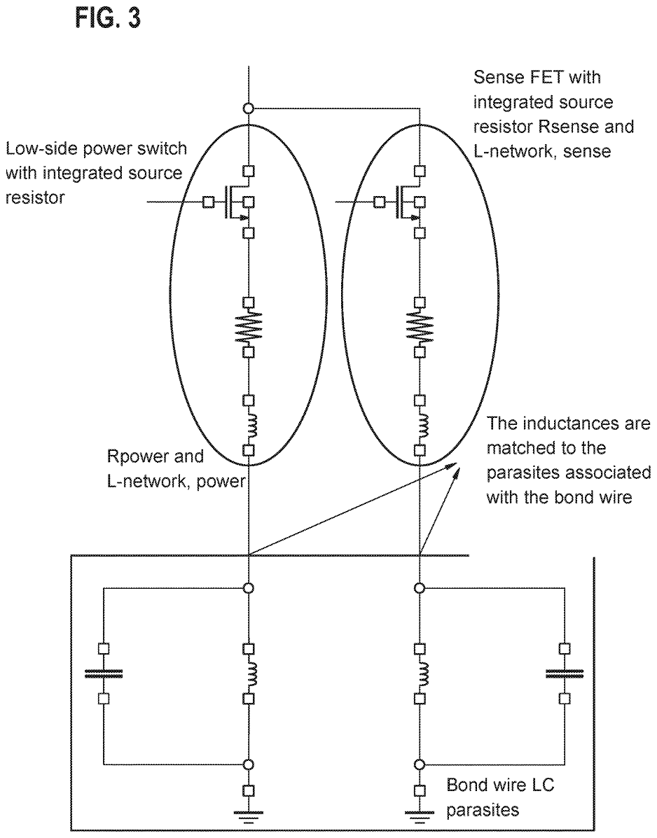

FIG. 3 shows a low-side power switch having an integrated sense FET and the associated impedance matching. In detail:
Low-side power switch: The power switch consists of the power FET (chem1250) and the source resistor R<sub>power</sub>(R31). The drain of the power FET is connected to VDRAIN_H (high-side drain), which indicates that this is part of a half-bridge circuit.
Sense FET: The sense FET (chem12_00) is connected in parallel to the power switch and shares the gate connection (VGATE). It has its own source resistor R<sub>sense</sub>(R36).
Impedance matching (L networks): Both the power switch and the sense FET have an LC network connected in series to the particular source resistor. The L network power: Consists of the inductor L<sub>power</sub>(L17) and the capacitor C<sub>power</sub>(C13). The L network sense: Consists of the inductor L<sub>sense</sub>(L24) and the capacitor C<sub>sense</sub>(C18).
Bond wire LC parasites: The dashed lines and the designation “bond wire LC parasites” illustrate that the L networks are intended to compensate for the parasitic inductances and capacitances of the bond wires. These bond wires connect the source connections of the transistors to the remainder of the circuit and can cause undesired impedance effects that impair the measurement accuracy.
Matching of the inductances: The inductances L<sub>power</sub>and L<sub>sense</sub> are matched to the parasitic inductances of the bond wires and have the same ratio relative to one another as the gate widths of the transistors, Lsense/Lpower=Wpower/Wsense=KSENSE. This is decisive for effectively compensating for the bond wire parasites.
Common connections: Both transistors share the gate connection (VGATE). However, the source connections are separated by the L networks and resistors. VSS_power is the source connection of the power FET including the L network and resistor, and VSS_sense is the source connection of the sense FET including the L network and resistor.

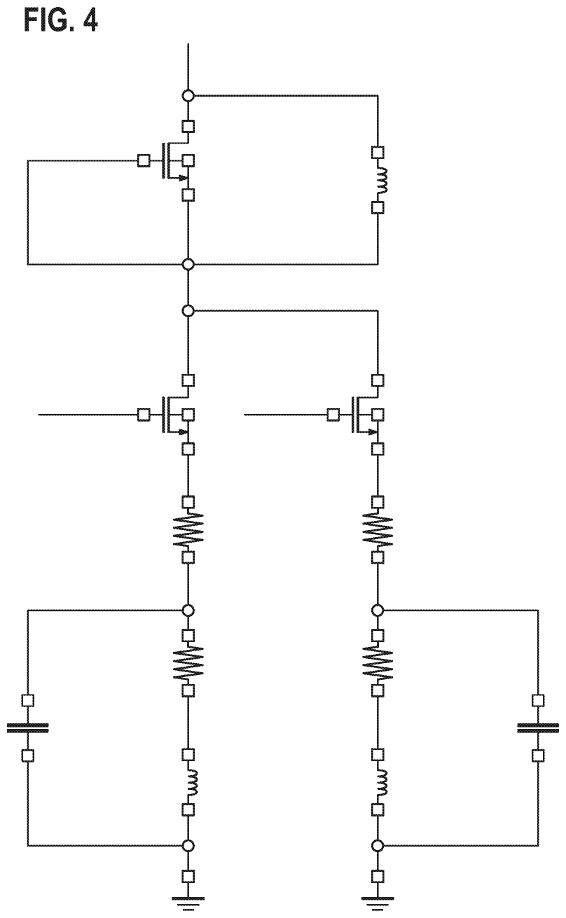

The circuit in FIG. 3 realizes precise current measurement by measuring the current through the sense FET, which is proportional to the current through the power FET. The L networks compensate for the bond wire parasites and minimize the difference between the source voltages (V<sub>SS_power</sub> and V<sub>SS_sense</sub>). This improves the accuracy and stability of the current measurement, in particular during fast switching transients. FIG. 3 represents the complete implementation of the present disclosure and shows how the impedance matching is integrated.
FIG. 4 shows the complete test setup for characterization of the current measurement. The half-bridge, consisting of the power FET, the sense FET, source resistors and L networks, is operated in double-pulse mode.
Half-bridge: The circuit contains two branches, one for the power FET and one for the sense FET. Each branch represents one side of the half-bridge.
Power FET (chem1250): The power FET has a gate width of 100 μm (specified as W=100u). The drain is connected to the node VPOWER. The source resistor is R<sub>power</sub>(R4).
Sense-FET (chem 12_00): The sense FET has a gate width of 40 μm (W=40u), which corresponds to the desired ratio KSENSE of 2500 (100 μm/40 μm=2.5). The drain is connected to the node VSENSE. The source resistor is R<sub>sense</sub>(R5).
Gate driver (Switch): The gate driver is symbolized by the switch “Switch.” It controls the gate voltages of both transistors (Vgate and Vatg). The gate width of the switch is specified as 100 μm (W=100u), which likely reflects the width of the power FET in the actual chip.
Impedance matching: As in FIG. 3, L networks for compensating for the bond wire parasites are provided:
   L network power: Consists of the inductor L<sub>power</sub>(L1) and the capacitor C<sub>power</sub>(C9).
   L network sense: Consists of the inductor L<sub>sense</sub>(L14) and the capacitor C<sub>sense</sub>(C1).
Measurement point PHASE: In a DPT configuration, as shown in FIG. 3, the node PHASE is connected to the gate of the HS switch. Therefore, the HS is switched off. The double-pulse signal is applied to the gate of the LS switch.
Further components:
   K1 and K2: capacitors for filtering.
   L8 and L17: inductors of which the function is not clearly evident from the diagram. They possibly serve for simulation of further parasitic effects or for filtering.
Double-pulse test: The double-pulse test provides for the separate examination of the turn-on and turn-off behavior of the transistors and minimizes thermal effects.

1-15. (canceled)

16. An integrated circuit for current measurement in a half-bridge, comprising:
a power transistor having a drain connection, a gate connection, and a first source connection;
a current sensing transistor having a drain connection, a gate connection, and a second source connection, wherein the gate connection of the power transistor is connected to the gate connection of the current sensing transistor;
a first source resistor connected to the first source connection of the power transistor;
a first impedance matching network connected in series to the first source resistor;
a second source resistor connected to the second source connection of the current sensing transistor; and
a second impedance matching network connected in series to the second source resistor;
wherein the first impedance matching network and the second impedance matching network are configured to compensate for parasitic inductances of bond wires.

17. The integrated circuit according to claim 16, wherein the first impedance matching network and the second impedance matching network each include an inductor and a capacitor connected in series.

18. The integrated circuit according to claim 17, wherein a ratio of an inductance of the first impedance matching network to an inductance of the second impedance matching network is equal to a ratio of a gate width of the power transistor to a channel width of the current sensing transistor.

19. The integrated circuit according to claim 16, wherein the drain connection of the power transistor is connected to the drain connection of the current sensing transistor.

20. The integrated circuit according to claim 16, wherein a ratio of a second source resistance of the second source resistor to a first source resistance of the first source resistor is equal to a ratio of a current through the power transistor to a current through the current sensing transistor.

21. The integrated circuit according to claim 16, wherein the current sensing transistor is integrated into an active region of the power transistor.

22. A method for current measurement in a half-bridge using an integrated circuit, the method comprising the following steps:
providing a power transistor (power FET) and a current sensing transistor (sense FET) having a common gate connection;
connecting a first source resistor to a source connection of the power FET and a second source resistor to a source connection of the sense FET;
integrating a first impedance matching network in series with the first source resistor, and a second impedance matching network in series with the second source resistor, wherein the first impedance matching network and the second impedance matching network each include at least one inductor and one capacitor and are configured to compensate for parasitic inductances of bond wires;
applying a control signal to the common gate connection;
measuring a current through the sense FET; and
determining a current through the power FET, based on the measured current through the sense FET and a predetermined current ratio.

23. The method according to claim 22, wherein the predetermined current ratio is defined by a ratio of a channel width of the power FET to a gate width of the sense FET.

24. The method according to claim 22, wherein the first impedance matching network and the second impedance matching network are dimensioned so that a ratio of their inductances corresponds to the predetermined current ratio.

25. The method according to claim 22, wherein drain connections of the power FET and the sense FET are connected to one another.

26. The method according to claim 22, wherein the first source resistor and the second source resistor are dimensioned so that a ratio of a second source resistance of the second source resistor to a first source resistance of the first source resistor corresponds to the predetermined current ratio.

27. The method according to claim 22, further comprising: integrating the sense FET into an active region of the power FET.

28. The method according to claim 22, wherein the measuring of the current through the sense FET includes measuring a voltage at the second source resistor.

29. The method according to claim 22, wherein the determining of the current through the power FET includes multiplying the measured current through the sense FET by the predetermined current ratio.

30. The integrated circuit according to claim 16, wherein the integrated circuit is used in a DC/DC converter or a motor drive.
